(19) United States
(12) Patent Application Publication
(10) Pub. No.: US 2026/0099098 A1
(43) Pub. Date: Apr. 9, 2026

(54) METHOD FOR MANUFACTURING A PROJECTION LENS, PROJECTION LENS, PROJECTION EXPOSURE SYSTEM, AND PROJECTION EXPOSURE METHOD

(71) Applicant: Carl Zeiss SMT GmbH, Oberkochen (DE)

(72) Inventors: Bernhard Stiftner, Oberkochen (DE); Michael Grupp, Aalen (DE); Hendrik Wagner, Aalen (DE); Johannes Michael Ostermann, Heidenheim (DE); Rumen Iliew, Oberkochen (DE); Reimar Finken, Westhausen (DE)

(21) Appl. No.: 19/415,199

(22) Filed: Dec. 10, 2025

Related U.S. Application Data
(63) Continuation of application No. PCT/EP2024/066044, filed on Jun. 11, 2024.

(30) Foreign Application Priority Data
Jun. 16, 2023 (DE) 102023115801.5

(51) Int. Cl. G03F 7/00; G02B 26/08

(52) U.S. Cl. CPC G03F 7/70266; G02B 26/0825; G03F 7/70508; G03F 7/70516; G03F 7/70525; G03F 7/70891; G03F 7/70958; G03F 7/70975

(57) ABSTRACT

Methods can produce a projection lens. Such a projection lens can be a component of a projection exposure apparatus. Such a projection exposure apparatus can be used in a lithography method.

### CROSS-REFERENCE TO RELATED APPLICATIONS

The present application is a continuation of, and claims benefit under 35 USC 120 to, international application No. PCT/EP2024/066044, filed Jun. 11, 2024, which claims benefit under 35 USC 119 of German Application No. 10 2023 115 801.5, filed Jun. 16, 2023. The entire disclosure of each of these applications is incorporated by reference herein.

### FIELD

The disclosure relates to a method for producing a projection lens, a projection lens produced with the aid of the method, a projection exposure apparatus and a projection exposure method.

### BACKGROUND

At present, microlithographic projection exposure methods are predominantly used for the production of semiconductor components and other finely structured components, for example microelectromechanical systems (MEMS). Here, use is made of masks (reticles) or other pattern generating devices, which carry or form the pattern of a structure to be imaged, for example a line pattern in a layer of a semiconductor component. The pattern is positioned in a projection exposure apparatus in the region of the object plane of a projection lens between an illumination system and the projection lens and is illuminated by illumination radiation provided by the illumination system. The radiation modified by the pattern travels as projection radiation through the projection lens, the latter imaging the pattern, usually in a reduced scale, onto the substrate to be exposed. The surface of the substrate is arranged in the image plane associated with the projection lens and optically conjugate to the object plane. The substrate is generally coated with a radiation-sensitive layer (resist, photoresist).

At present, projection exposure apparatuses with high-resolution projection lenses operate at wavelengths shorter than 260 nm in the deep ultraviolet (DUV) range or in the extreme ultraviolet (EUV) range, e.g. at wavelengths between 6 nm and 20 nm. In general, they have a multiplicity of optical elements so as to meet partly conflicting desired properties with regard to the correction of imaging aberrations possibly even with large numerical apertures used. In the field of microlithography, both refractive and catadioptric projection lenses frequently have ten or more transparent optical elements. In systems for EUV lithography it is generally endeavored to manage with the fewest possible reflective elements, e.g. with four or six mirrors.

In projection lenses, the overall imaging errors are given by the sum of the errors of the individual optical elements that contribute to the imaging. Since error tolerances for individual components cannot be reduced at will, an adjustment of the overall system is generally used in order to minimize the overall errors in the system. For high-performance microlithographic projection lenses, for example, such an adjustment process is very complex. Without a complicated adjustment, it is generally the case that the desired imaging performances with resolutions in the sub-micrometer range cannot be attained in these complex optical systems.

In general, an adjustment process comprises multiple different manipulations of lens elements and/or mirrors and/or other optical elements. These include lateral displacements of the elements perpendicular to a reference axis, displacements along the reference axis for the purpose of changing spacings, rotations and/or tilts of elements. The adjustment procedure is performed under monitoring by way of a suitable aberration measurement of the projection lens in order to be able to check the effects of the manipulations and derive instructions for further adjustment steps.

Residual errors may remain even after a complicated adjustment, and in general these can only be eliminated with significantly increased adjustment outlay or possibly by adjustment not at all. Further measures for improving the imaging performance are used should the errors exceed the specifications predefined for the optical system. One measure lies in the introduction of what are known as “correction aspheres” into the optical imaging system. These are frequently also referred to by the abbreviation ICA (integrated correction asphere). Residual errors that might be present can be further minimized by using correction aspheres.

U.S. Pat. No. 6,268,903 B1 (corresponding to EP 724 199 B1) describes an adjustment method for an optical imaging method, for the purposes of which a correction element is manufactured on the basis of a distortion measurement. To this end, a correction element which is part of the projection lens is provided at a predetermined location in the imaging system. After the distortion of the system has been measured, the topography of the surface of the correction element that is used to eliminate the corresponding distortion component is calculated. The correction element is subsequently removed from the projection system, and the correction surface is processed. Afterwards, the correction element is inserted again.

U.S. Pat. No. 5,392,119 (cf. also WO 96/07075) describes a method for correcting aberrations in an optical imaging system, in which at least one imaging error is measured on the imaging system, for example distortion, field curvature, spherical aberration, coma or astigmatism. Correction plates that are adapted for the imaging system on an individual basis are manufactured on the basis of the measurements, and the correction surfaces of the correction plates serve to minimize the measured imaging errors. In this way, “spectacles” can be tailor-made retrospectively for an imaging system. This can improve the imaging performance of existing imaging systems.

Document DE 102 58 715 A1 (corresponding to U.S. Pat. No. 7,283,204 B2) discloses a method for producing a microlithographic projection lens, wherein the projection lens is measured post assembly in order to determine the wavefront in the exit pupil or on a surface of the imaging system conjugate thereto in a spatially resolved manner and manufacture a near-pupil correction surface on the basis thereof. In this case, the surface provided as a correction surface is initially left uncoated during the installation, is then processed after removal, e.g. via ion beam etching, and is then coated prior to reinstallation.

U.S. Pat. No. 10,001,631 B2 describes a projection lens for EUV microlithography and a method for producing an EUV projection lens, wherein one or more radiation-transmissive film elements are introduced into the projection lens at a suitable location in the beam path, and these film elements are capable of influencing the local wavefront two-dimensionally in the sense of a correction asphere by targeted control of the thickness distribution of the individual layers of the film over the optically clear region.

Besides the intrinsic imaging errors that a projection lens may have on account of its optical configuration (its optical design) and the production, imaging errors may also occur during the use period, for example during the operation of a projection exposure apparatus on the part of the user. Such imaging errors are often caused by changes in the optical elements installed in the projection lens as a result of the projection radiation employed during use. This is often dealt with under the heading “lens heating”. Other internal or external disturbances can also lead to the impairment of the imaging performance. They include, inter alia, a possible scale error of the mask, changes in the air pressure in the surroundings, differences in the strength of the gravitational field between the location of the original lens adjustment and the location of use by the customer, changes in refractive index and/or shape alterations of optical elements on account of material modifications as a result of high-energy radiation (e.g. compaction), deformations on account of relaxation processes in the holding devices, drifting of optical elements and the like.

Modern microlithographic projection exposure apparatuses comprise an operating control system which allows a near-instantaneous fine optimization of imaging-relevant properties of the projection exposure apparatus to be performed in reaction to environmental influences and other disturbances. To this end, at least one manipulator is activated in a manner appropriate for the current system state in order to counteract an undesirable effect of a disturbance on the imaging performance. In this case, the system state may be estimated e.g. on the basis of measurements, from a simulation and/or on the basis of calibration results or may be ascertained in some other way.

The operating control system comprises a subsystem, belonging to the projection lens, in the form of a wavefront manipulation system for dynamically influencing the wavefront of the projection radiation traveling from the object plane to the image plane of the projection lens. In the course of dynamic influencing, the effect of the components of the wavefront manipulation system that are arranged in the projection beam path can be set in a variable manner on the basis of control signals of the operating control system, whereby the wavefront of the projection radiation can be modified in a targeted manner. The optical effect of the wavefront manipulation system can be modified e.g. in the case of specific, predefined occasions or in a manner depending on the situation prior to an exposure or else during an exposure.

The wavefront manipulation system comprises at least one manipulator comprising at least one manipulator element having at least one manipulator surface arranged in the projection beam path. A manipulator comprises an actuating device for reversibly changing the optical effect of the manipulator element on the basis of corresponding control signals of the operating control system of the projection exposure apparatus. The optical effect may be modified e.g. by modifying the surface shape of a manipulator surface and/or by modifying the refractive index distribution within the manipulator element. The modification may be designed such that an arising error is at least partially compensated thereby.

Manipulators may operate according to different principles. Examples are described inter alia in the following documents: U.S. Pat. No. 7,112,772 B2; WO 2008/080537 A1; WO 2022/074022 A1; US 2009/257032 A1; and U.S. Pat. No. 9,651,872 B2.

### SUMMARY

The disclosure seeks to provide a resource-saving method for producing a projection lens, the method enabling, with justifiable outlay, the development of projection lenses with an excellent correction state over long periods of use. For example, the intention is to provide a method that allows the production of projection lenses that hitherto have only been able to be brought to a sufficiently small residual error level using at least one individually processed correction asphere.

In an aspect, the disclosure provides a method for producing a projection lens for imaging a pattern arranged in an object plane of the projection lens into an image plane of the projection lens, including the following steps: assembling the projection lens by arranging a multiplicity of optical elements in accordance with a specification, in such a way that optical surfaces of the optical elements form a projection beam path via which a pattern arranged in the object plane can be imaged into the image plane via the optical elements, wherein at least one manipulator of a wavefront manipulation system is installed in order to dynamically influence the wavefront of the projection radiation in response to control signals from a control unit of the wavefront manipulation system, wherein the manipulator comprises at least one manipulator element with at least one manipulator surface arranged in the projection beam path and an actuating device which is controllable by control signals from the control unit and which serves to reversibly change the optical effect of the manipulator element; measuring the projection lens with a spatially resolved determination of the wavefront for spatially resolved determination of wavefront errors, wherein the manipulator element has an initial configuration during the measurement; calculating a first configuration of the manipulator element that is suitable for correcting the wavefront errors; and defining a first mode of operation of the control unit, wherein the control unit generates first control signals in the first mode of operation. The first control signals prompt the actuating device to set the first configuration of the manipulator.

In an aspect, the disclosure provides a projection lens for imaging a pattern arranged in an object plane of the projection lens into an image plane of the projection lens, comprising: a multiplicity of optical elements which are arranged in such a way that optical surfaces of the optical elements form a projection beam path in such a way that a pattern arranged in the object plane can be imaged into the image plane via the optical elements; and a manipulator of a wavefront manipulation system for dynamically influencing the wavefront of the projection radiation in response to control signals from a control unit of the wavefront manipulation system, wherein the manipulator comprises at least one manipulator element having at least one manipulator surface arranged in the projection beam path and an actuating device controllable by control signals from the control unit for reversibly changing the optical effect of the manipulator element. The manipulator element has an initial configuration, and the projection radiation has wavefront errors during operation in the initial configuration of the manipulator element. A first operating data record which represents a first mode of operation is stored in a data memory accessible to the control unit, and the control unit is configured to generate first control signals in the first mode of operation. The first control signals prompt the actuating device to set a first configuration of the manipulator element that is suitable for correcting the wavefront errors.

In an aspect, the disclosure provides a projection exposure method for exposing a radiation-sensitive substrate with at least one image of a pattern of a mask, including the following steps: providing a pattern between an illumination system and a projection lens of a projection exposure apparatus, in such a way that the pattern is arranged in the region of the object plane of the projection lens; holding the substrate in such a way that a radiation-sensitive surface of the substrate is arranged in the region of an image plane of the projection lens that is optically conjugate to the object plane; illuminating an illumination region of the mask with an illumination radiation provided by the illumination system; projecting a part of the pattern lying in the illumination region onto an image field on the substrate with the aid of the projection lens, wherein all rays of the projection radiation contributing to the image generation in the image field form a projection beam path; and influencing the wavefront of the projection radiation traveling from the object plane to the image plane by activating a manipulator that comprises a manipulator element having at least one manipulator surface arranged in the projection beam path and a first actuating device for reversibly changing an optical effect of the manipulator element. The manipulator element has an initial configuration in the absence of control signals, and the projection radiation has wavefront errors during operation in the initial configuration of the manipulator element. A first operating data record which represents a first mode of operation is stored in a data memory accessible to the control unit. The control unit, exclusively on the basis of the first operating data record, switches into a first mode of operation and generates first control signals which prompt the actuating device to set a first configuration of the manipulator element that is suitable for correcting the wavefront errors.

In an aspect, the disclosure provides a method for repairing a projection lens having a multiplicity of optical elements which are arranged in accordance with a specification, in such a way that optical surfaces of the optical elements form a projection beam path via which a pattern arranged in the object plane can be imaged into the image plane via the optical elements. At least one of the optical elements is configured, as a correction element, to influence the local wavefront two-dimensionally in a region located in the projection beam path, in the manner of a fixed correction asphere that is individually adapted for the projection lens. The method comprises the following steps: removing an assembly comprising the correction element; and installing a replacement assembly instead of the assembly comprising the correction element. The replacement assembly comprises a manipulator of a wavefront manipulation system for dynamically influencing the wavefront of the projection radiation in response to control signals from a control unit of the wavefront manipulation system. The manipulator comprises at least one manipulator element with at least one manipulator surface arranged in the projection beam path and an actuating device which is controllable by control signals from the control unit and which serves to reversibly change the optical effect of the manipulator element. The manipulator element has an initial configuration, and the projection radiation has wavefront errors during operation in the initial configuration of the manipulator element. A first operating data record which represents a first mode of operation is stored in a data memory accessible to the control unit. The control unit is configured to generate first control signals in the first mode of operation. The control signals prompt the actuating device to set a first configuration of the manipulator element in which the manipulator element substantially has the optical effect of the removed correction asphere.

According to one way of phrasing the disclosure, a method is provided for producing a projection lens that is designed to image a pattern arranged in an object plane of the projection lens into an image plane of the projection lens. In this context, the projection lens is assembled by arranging a multiplicity of optical elements in accordance with a specification, in such a way that optical surfaces of the optical elements form a projection beam path via which a pattern arranged in the object plane can be imaged into the image plane with the aid of the optical elements.

The assembly of the projection lens includes the installation of at least one manipulator of a wavefront manipulation system that is designed to dynamically influence the wavefront of the projection radiation in response to control signals from a control unit of the wavefront manipulation system. Here, the term “dynamic” means that the optical effect of the manipulator can be modified by way of appropriate activation. Such a manipulator has at least one manipulator element with at least one manipulator surface arranged in the projection beam path and an actuating device which is controllable by control signals from the control unit and which serves to reversibly change the optical effect of the manipulator element. A manipulator contains one or more actuating members or actuators, the current manipulated value of which can be changed or adjusted by way of a manipulated value change on the basis of control signals from the operating control system. A manipulated value change may e.g. bring about a displacement or a deformation of a manipulator element or lead to a change in the temperature distribution in the optically used region.

The method comprises at least one measurement operation, in which the wavefront of the projection radiation is measured in spatially resolved fashion in order to determine possible wavefront errors in spatially resolved fashion. To the end, the entire wavefront can be measured in spatially resolved fashion, i.e. for many field points, in the vicinity of a field plane, for example in the vicinity of the image plane. The wavefront at a specific field point may be described as a phase retardation plotted over two-dimensional pupil coordinates, and it is also spatially resolved in angular space in this respect. This two-dimensionally angle-resolved wavefront may be measured at many field points, i.e. with spatial resolution. Field-point-resolved wavefront errors are obtainable as a result.

For this measurement operation, the manipulator element has an initial configuration. In this case, the initial configuration is the configuration of the manipulator element during the first measurement operation, with the first measurement operation being the measurement operation serving to establish the initial state of the projection lens after assembly. In the initial configuration, the manipulator element has a specific optical effect that is known or at least determinable.

For example, the initial configuration may be a neutral configuration of the manipulator element. Here, the term “neutral configuration” denotes a configuration in which the optical effect of the manipulator element corresponds to the intended effect of the manipulator element according to the optical design of the projection lens. The neutral configuration can be described as a configuration that the manipulator element would have in the ideal case if all optical surfaces of the projection lens, including the manipulator element, were embodied exactly in accordance with the intended configuration that emerges from the optical design calculations. The further procedure is simplified by this case, in which the initial configuration corresponds to the neutral configuration. It is usually present when a new manipulator element which has never been used before is installed.

However, the initial configuration of the manipulator element need not correspond to its neutral configuration but may deviate significantly therefrom. For example, this may be the case if, by way of recycling, a manipulator element which has already been used in another projection lens, i.e. an already used manipulator element, is installed, the latter having been provided with a permanent, individual correction asphere in order to ensure that the other projection lens met the specifications. For the use in the newly assembled projection lens, the optical effect of this correction asphere can then be neutralized or compensated for.

It is very probable that the wavefront measured during the measurement operation will deviate from the wavefront (according to specification) desired under ideal circumstances. Hence the measurement operation will establish a wavefront error which quantitatively represents the deviation of the measured wavefront from the sought-after target wavefront. Such deviations from the ideal state are typical, inter alia on account of unavoidable manufacturing errors during the manufacture of the individual optical elements and unavoidable errors during the assembly and during the adjustment of the projection lens.

The method comprises a calculation operation in which a first configuration of the manipulator element that is suitable for correcting the wavefront error is calculated. In general, the first configuration differs significantly from the initial configuration, in which wavefront errors are still present, and specifies the manner in which the manipulator element would have to be configured in order to remove the wavefront errors established during the measurement operation or in any case compensate the wavefront errors to such an extent that the imaging performance of the projection lens meets the specifications. For example, the first configuration may differ from the initial configuration in that a manipulator surface of a manipulator element has a different topography or surface shape in the first configuration compared to the initial configuration. In an alternative to that or in addition, the first configuration may also have a different local refractive index distribution within the manipulator element to the initial configuration.

The property of the manipulator element that is modified in order to correct the wavefront errors depends inter alia on the type of manipulator. For example, if the manipulator is a mirror with a deformable mirror surface, then the topography of the mirror surface acting as a manipulator surface will change between the initial configuration and the first configuration. By contrast, if the manipulator element is a radiation-transmissive optical element, it may be the case that substantially only the refractive index distribution within the optically used region of the manipulator element changes during the transition from the initial configuration to the first configuration. For example, this may be the case if the manipulator is a transparent optical element that is heated and/or cooled to different extents electrically or in any other way in order to change the local refractive index distribution at different locations in the used region. In some manipulators, there is a change both in the topography of at least one manipulator surface and in the refractive index distribution in the optically used region (used region) of the manipulator element when the manipulated value changes.

For understanding this aspect of the disclosure, it is to be noted here that the first configuration of the manipulator element is a configuration which is individualized for the respective state of the projection lens on the basis of the underlying measurement. The first configuration is suitable for the compensation of those errors that were accumulated precisely in the case of this projection lens, e.g. as a result of preceding manufacturing steps, and could not be eliminated by the preceding adjustment operations either.

As a further step, the method comprises defining a first mode of operation of the control unit, wherein the control unit generates first control signals in the first mode of operation, the first control signals prompting the actuating device to set the first configuration of the manipulator element. This definition step represents the creation of a prescription containing all parameter values that have to be set with the aid of the control unit in order to bring the manipulator into the first configuration and hence ensure that the imaging performance of the projection lens meets the specifications. The prescription need not be implemented or realized in practice during the adjustment. The prescription is used in later use phases.

The first mode of operation can be considered to be a static mode of operation. The manipulator operated in the first mode of operation in this case replaces the effect of the conventional, individually adapted correction aspheres. Expressed in yet another way: The imaging performance of the projection lens will regularly not meet the desired behavior for operation for as long as the projection lens is operated with a manipulator that is installed but in the neutral configuration and/or not activated. The imaging performance is achieved when the manipulator is activated by the control unit in accordance with the first mode of operation, i.e. when the manipulator is activated and adopts the first configuration.

This aspect of the disclosure can also be described as a conventional correction asphere, which was produced for a projection lens on an individual basis and brings about the corresponding correction only for the individual projection lens, being able to be replaced by a dynamically activatable manipulator, which, in the first mode of operation, can be activated in such a way that it is capable of replacing the effect of the conventional correction asphere.

The the assembly and adjustment steps can be performed by the projection lens manufacturer at a manufacturing site, while the projection lens is used by a customer at a remote use site. Following the adjustment, the projection lens may be supplied in a state which is not yet fully functional and in which the manipulator is not activated and is accordingly in the initial configuration, e.g. in the neutral configuration. In that case, the projection lens is used productively within the scope of a production operation at the use site following its installation in a projection exposure apparatus. To this end, the control unit is switched into the first mode of operation before the production operation starts and generates first control signals that prompt the actuating device to set the first configuration of the manipulator element. As a result, the imaging performance meets the specifications.

In order to ensure that the manipulator can quickly and easily meet the specifications at the site of its use, provision can be made for a first operating data record representing the first mode of operation to be stored in a data memory accessible to the control unit. In that case, the content of the memory can easily be retrieved within the scope of commissioning the projection lens at the use site, and so the control unit is able to activate the manipulator in such a way that the first configuration is set. The correction prescription ascertained with the scope of the measurement operation is thus made available as software or in the form of data at the use site and can be set there without a renewed measurement of the lens.

The manipulator can continue to remain a dynamically activatable manipulator and can still adopt further functions during the operational time of the projection lens or even later. According to a development, provision is made for the control device to be operable in multiple modes of operation, wherein in addition to the first mode of operation—and optionally proceeding from the latter—it is possible to set at least one second mode of operation in which the manipulator element has a second configuration that has a different optical effect than the first configuration. In contrast to a conventional correction asphere, the dynamic component of the manipulator is used here in order to compensate for possible components of wavefront errors that occur during operation. Thus, the manipulator can be reconfigured within the projection lens in order to be operated with a second configuration which is suitable for restoring a correction state possibly lost over the period of use or avoiding the case where the projection lens fails to meet the specification during operation, for example on account of thermal effects. The manipulator can thus exert a dual function, specifically that of replacing a conventional correction asphere when the first configuration is set and acting as a dynamically activatable correction mechanism for wavefront errors arising for operational reasons in a second configuration.

In general, the adjustment of microlithographic projection lenses is a relatively complex, time-consuming process since there are very many degrees of freedom for improving the imaging performance but also for worsening the imaging performance. In order to provide sufficient degrees of correction freedom, at least one further manipulator can be installed in addition to the manipulator. In that case, suitable configurations are likewise found for the further manipulator. In this case, the adjustment can be an iterative process, in which it comes down to limiting the outlay in terms of time as far as possible and performing the adjustment in such a way that the adjustment process systematically converges to a sufficient correction state.

In this case, it was found to be expedient for the effect of activating the manipulator for setting the first configuration to be taken into account by simulation during the adjustment, without the manipulator actually being activated, with the effects of the (one or more) further manipulators actually being implemented. In this case, the first configuration of the manipulator may be subjected to multiple minor modifications within the individual adjustment loops in order to likewise compensate residual errors when setting other manipulators, this being performed until a first configuration is found which is suitable for sufficiently compensating all residual errors of the projection lens, including those originating from other manipulators.

Even though these days extremely tight manufacturing tolerances can be observed in the production of projection lenses, each projection lens has an individual set of wavefront aberrations that can subsequently be compensated for by an individually made correction asphere. However, in that case a conventional correction asphere is only useful in a single projection lens and after being used therein it either cannot be used at all or can possibly be used for other purposes only after complex reprocessing. By contrast, certain embodiments provide for the manipulator to be removed from a projection lens after its period of use in the projection lens has elapsed and, after removal, to be used as a manipulator element in a further projection lens. In that case, too, the scope of the first adjustment may again comprise determining a first configuration in which the manipulator element may act as a substitute for a correction asphere, with this first configuration generally differing significantly from that set in the other projection lens.

Thus, despite the possibility of individualizing the optical effect for a specific projection lens, manipulators according to this proposal can still be reused as manipulator in other projection lenses even after a use phase in this projection lens. Such “recycling” allows considerable saving of resources, and costs can significantly be saved without any loss in the sought-after optical correction effect.

In comparison with the conventional concept of the correction asphere, the novel concept also offers desirable properties in view of the optimization of optical properties of the manipulator element. In some conventional methods, the surface of an optical element that is envisaged as correction surface initially remained uncoated during the installation. The measurements were performed with an uncoated manipulator surface. Afterwards, the manipulator element was removed again, and the correction surface was processed via ion beam etching in order to modify the surface shape such that the desired correction effect occurs. Thereafter, the manipulator element, which was already mounted in its mount, was reinstalled. Hence the coating process was undertaken on a manipulator element which was already held by its mount.

In some embodiments of the method proposed in this application, by contrast, the manipulator surface is coated with an optical functional layer prior to installation in the projection lens. The coating operation can be implemented prior to the installation of the manipulator element in its mount. This can facilitate the logistics, inter alia.

According to another aspect of the disclosure, provision is made of a projection lens of the type mentioned in the introduction, in which, in the absence of control signals, the manipulator element of the manipulator has an initial configuration, for example a neutral configuration, and the projection radiation has wavefront errors during operation when the manipulator element has the neutral configuration or any other initial configuration as initial configuration. A peculiarity now consists in the fact that a first operating data record which represents a first mode of operation is stored in a data memory accessible to the control unit, and that the control unit is configured to generate first control signals in the first mode of operation, the first control signals prompting the actuating device to set a first configuration of the manipulator element that is suitable for correcting the wavefront errors.

Hence, initially, i.e. when the manipulator has not yet been activated for example, the projection lens is not yet capable of offering the imaging performance specified according to the specification. However, during commissioning, the user can ensure that the projection lens meets the specifications by virtue of the control unit being switched into the first mode of operation which causes the manipulator to be changed over in such a way that, in accordance with a first configuration, the manipulator element is designed such that the wavefront error is corrected at least so comprehensively that the specification is met.

The result of the measurement operation performed within the scope of the adjustment is thus transferred for later use to the manipulator element via software. During further operation of the projection lens, the manipulator element may then also adopt at least one second configuration, which deviates from the first configuration, in order to additionally also compensate for wavefront error components that still occur during operation.

The disclosure also relates to a projection exposure apparatus which is equipped with such a projection lens and/or is configured to perform the projection exposure method.

Features of aspects of the disclosure can be used not only in the new production or initial production of projection lenses but also in the context of a repair or a restoration of a projection lens, which e.g. after prolonged use involves maintenance or repair. As already mentioned above, a manipulator of the type described here can be used inter alia as a substitute for a conventional correction asphere, specifically by virtue of a first configuration, by which the effect of the conventional correction asphere to be replaced can be achieved, being set on the manipulator. A “conventional correction asphere” within the meaning of this application may be e.g. an aspherically curved surface of a lens element or of a mirror, the surface shape of which in a targeted manner serves to partially or completely compensate for aberration components of an optical system that are caused by manufacturing errors. In general, the correction asphere is a correction asphere which is adapted to the projection lens on an individual basis, which is substantially fixed in terms of its effect and which can be used to correct residual aberrations remaining after the adjustment.

These days, there are many projection lenses in which at least one of the optical elements, as a correction element, is configured to influence the local wavefront two-dimensionally in a region located in the projection beam path, in the style of such a fixed correction asphere that is adapted for the projection lens on an individual basis. For example, a correction asphere on an optical element provided for in the optical design may be created by virtue of an optical surface of this element being processed to different extents locally via ion beam processing and/or in some other way in order to attain the sought-after correction effect. For example, such correction aspheres may be formed on transparent plane plates, but optionally also on plane or curved lens element surfaces that may have a spherical or rotationally symmetrically aspherical form prior to the creation of the correction asphere and may have a no longer rotationally symmetric form after the introduction of the correction asphere.

If after prolonged use of the projection lens there is now the risk of the projection lens no longer meeting the specifications within a foreseeable period of time, for example on account of radiation-induced degradation effects or the like, then this may be remedied by a repair. To this end, according to a method proposed herein for repairing a projection lens, an assembly comprising the correction element with the (conventional) correction asphere is removed from the projection lens, and a replacement assembly is installed instead of the assembly comprising the correction element. In this case, the replacement assembly comprises a manipulator of the type described here, the manipulator element of which has an initial configuration, for example a neutral configuration, which causes the projection radiation to have a wavefront error during operation with the initial configuration of the manipulator element. In this context, the repair comprises a step in which a first operating data record which represents a first mode of operation is stored in a data memory accessible to the control unit of the projection lens. The control unit is configured to generate first control signals in the first mode of operation, the control signals prompting the actuating device of the manipulator to set a first configuration of the manipulator element in which the manipulator element substantially has the optical effect of the removed correction asphere. Using this, a conventional correction asphere that is fixed in terms of its optical effect as a matter of principle may be replaced by a correction asphere, created by activating the manipulator, of identical or virtually identical optical effect.

A repair kit for repairing a projection lens comprises a combination of hardware components and software components. The hardware components include the replacement assembly having the manipulator that can be activated by way of the control unit. The software components include the first operating data record which should be stored in the data memory accessible to the control unit and which enables the control unit to assume the first mode of operation that then leads to the manipulator, which is usable in an adaptable manner per se, being set in such a way that it has the effect of the conventional fixed correction asphere. The data of the first operating data record may be determined computationally and/or on the basis of measurements.

In general, such a repair kit can be used repeatedly. In other words, such a repair kit is universally usable in a certain sense since the combination of hardware and software components is able to replace differently designed conventional, fixed correction aspheres. The individualization here is based not on a fixed physical property of the correction element but is realized by way of appropriate activation.

Such repair measures may be performed on differently constructed projection lenses. For example, it may be the case that a projection lens already comprises a dynamically usable manipulator of a wavefront manipulation system, the manipulator element of which, for example a transparent lens element or a transparent plate, is provided with an individually manufactured correction asphere in order to be able to meet the specification of the projection lens within the scope of the initial production. In this case, the assembly having the correction element already comprises a manipulator element and actuating devices for reversibly changing the optical effect of the manipulator element. Such a manipulator, which has become in need of maintenance or repair and which has been provided with the aid of a conventional correction asphere in order to meet the specification of the projection lens, can thus be removed on site at the user of the projection lens and be replaced by a structurally equivalent manipulator without a correction asphere (or a structurally equivalent or compatible manipulator with another correction asphere) in order to ensure that the projection lens then meets the specifications in terms of the wavefront errors again by way of a suitable activation in accordance with the described concept.

It is also possible to replace a conventional, non-manipulable correction element with a correction asphere by a manipulator of the type described herein, which is activatable in the first mode of operation. For example, after the initial production, a projection lens may comprise a transparent plane plate in the optical vicinity of a pupil plane. This plane plate with a correction asphere may be replaced by a manipulator described herein and having a plane-plate-like manipulator element, wherein the effect of the correction asphere may then be set in a controlled manner via software.

It is also possible within the scope of a repair to leave a conventional correction element with a correction asphere, which no longer has the desired corrective effect, in the projection lens and to install a manipulator of the type described herein at a location that is optically conjugate to the position of the correction element which no longer functions sufficiently. In that case, it is possible to set a corrective effect that at least approximately corrects the error that has arisen in the meantime.

The present application also discloses novel concepts for recycling optical components for wavefront correction in projection lenses. As already mentioned, it may be the case that a projection lens already in use comprises a dynamically usable manipulator of a wavefront manipulation system, the manipulator element of which is provided with an individually manufactured correction asphere in order to meet the imaging specification in the projection lens in which it is installed. For as long as this manipulator is functional in principle, it may optionally also be used in other projection lenses. Hence, such manipulators are suitable for recycling. For example, a still functional manipulator of this type can be removed from an old installation environment of the projection lens in which it was used previously (first projection lens) and reused in another projection lens (second projection lens). This other projection lens (second projection lens) may for example be a projection lens to be repaired, which comprises a structurally identical or compatible dynamically usable manipulator, the manipulator element of which does not comprise an individually manufactured correction asphere. The recycled manipulator (the manipulator with the correction asphere individually adapted to an old projection lens) can now be used as a manipulator in the other projection lens (second projection lens), e.g. in a projection lens to be repaired. In that case, this projection lens (the second projection lens) will have wavefront errors in the initial configuration, and these wavefront errors are traced back to the correction asphere (which does not fit the new projection lens). In this case, this initial configuration will deviate significantly from a neutral configuration.

The unwanted effect contribution of the correction asphere (not adapted to the second projection lens) may however be taken into account in the calculation of the first mode of operation of the manipulator. The manipulator can be operated in a first mode of operation which firstly compensates for the effect of the (ill-fitting) correction asphere and secondly also compensates for those aberration components which arise in the context of the assembly of the repaired projection lens. Hence, this is a case in which the initial configuration during the measurement operation there does not correspond to the neutral configuration of the manipulator.

An analogous recycling procedure for a dynamically usable manipulator is also possible if the projection lens to be repaired is provided by way of installation with a dynamic manipulator that was provided with a correction asphere adapted to this projection lens on an individual basis.

### BRIEF DESCRIPTION OF THE DRAWINGS

Further features and aspects of the disclosure are evident from the claims and from the following description of certain exemplary embodiments of the disclosure, which are explained below with reference to the figures.

FIG. 1 shows a microlithographic projection exposure apparatus according to one exemplary embodiment of the disclosure;

FIG. 2 schematically shows a plan view of an exemplary embodiment of a transparent manipulator with integrated thin heating conductors;

FIGS. 3A-C shows, in each of the three partial FIGS. 3A, 3B and 3C, different configurations of the manipulator and the corresponding optical effect thereof on the wavefront error;

FIGS. 4A and 4B show schematic illustrations of two-dimensional heating profiles according to a conventional method;

FIGS. 5A and 5B show heating profiles according to one exemplary embodiment, with FIG. 5A showing the first configuration and FIG. 5B showing a second configuration deviating therefrom; and

FIGS. 6A, 6B and 6C illustrate two different scenarios for repairing a projection lens.

### DETAILED DESCRIPTION

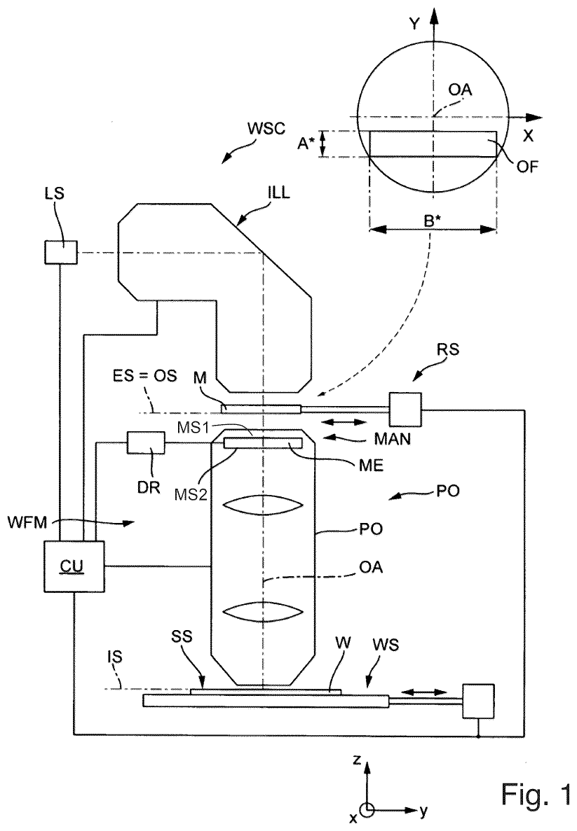

FIG. 1 shows an example of a microlithographic projection exposure apparatus WSC which is usable in the production of semiconductor components and other finely structured components and which operates with light or electromagnetic radiation from the deep ultraviolet (DUV) range in order to obtain resolutions down to fractions of micrometers. An ArF excimer laser with an operating wavelength λ of approximately 193 nm serves as primary radiation source or light source LS. Other UV laser light sources, e.g. F₂ lasers with an operating wavelength of 157 nm or KrF excimer lasers with an operating wavelength of 248 nm, are also possible.

At its exit surface ES, an illumination system ILL disposed downstream of the light source LS generates a large, sharply delimited and substantially homogeneously illuminated illumination field, which is adapted to the desired telecentricity of the projection lens PO arranged downstream thereof in the light path. The illumination system ILL has devices for setting different illumination modes (illumination settings) and can be switched for example between conventional on-axis illumination with different degrees of coherence and off-axis illumination.

Those optical components which receive the light from the light source LS and shape illumination radiation from the light, which illumination radiation is directed to the illumination field lying in the exit plane ES or to the reticle M, are part of the illumination system ILL of the projection exposure apparatus.

Arranged downstream of the illumination system is a device RS for holding and manipulating the mask M (reticle) in such a way that the pattern arranged at the reticle lies in the region of the object plane OS of the projection lens PO, which coincides with the exit plane ES of the illumination system and which is also referred to here as reticle plane OS. For the purposes of scanner operation, the mask is movable parallel to this plane in a scanning direction (y-direction) perpendicular to the optical axis OA (z-direction) with the aid of a scanning drive. The device RS comprises an integrated lifting device for linearly displacing the mask in relation to the object plane in the z-direction, i.e. perpendicular to the object plane, and an integrated tilting device for tilting the mask about a tilt axis extending in the x-direction.

Following downstream of the reticle plane OS is the projection lens PO, which acts as a reduction lens and images an image of the pattern arranged at the mask M with a reduced scale, for example with the scale of 1:4 (|β|=0.25) or 1:5 (|β|=0.20), onto a substrate W coated with a photoresist layer, the light-sensitive substrate surface SS of which lies in the region of the image plane IS of the projection lens PO.

The substrate to be exposed, which is a semiconductor wafer W in the exemplary case, is held by a device WS, which comprises a scanner drive in order to move the wafer synchronously with the reticle M perpendicular to the optical axis OA in a scanning direction (y-direction). The device WS furthermore comprises a lifting device for linearly displacing the substrate in relation to the image plane in the z-direction and a tilting device for tilting the substrate about a tilt axis extending in the x-direction.

The device WS, which is also referred to as “wafer stage”, and the device RS, which is also referred to as “reticle stage”, are constituent parts of a scanner device which is controlled by way of a scan control device which, in the embodiment, is integrated in the central control device CU of the projection exposure apparatus.

The illumination field generated by the illumination system ILL defines the effective object field OF used during the projection exposure. In the exemplary case, the latter is rectangular, has a height A* measured parallel to the scanning direction (y-direction) and has a width B*>A* measured perpendicular thereto (in the x-direction). In general, the aspect ratio AR=B*/A* lies between 2 and 10, for example between 3 and 6.

In the exemplary case, the projection lens PO is a catadioptric projection lens, which may comprise a single concave mirror or two concave mirrors.

The effective object field lies at a distance next to the optical axis in the y-direction (off-axis field). The effective image field in the image surface IS, which is optically conjugate to the effective object field, likewise is an off-axis field and has the same shape and the same aspect ratio between the height B and width A as the effective object field; the absolute field dimension is reduced by the imaging scale β of the projection lens, i.e. A=|β|A* and B=|β|B*.

It is also possible to use a dioptric projection lens; in that case, an object field that is centered with respect to the optical axis can be used.

If the projection lens is designed and operated as an immersion lens, then radiation is transmitted through a thin layer of an immersion liquid during the operation of the projection lens, the thin layer being situated between the exit surface of the projection lens and the image plane IS. Image-side numerical apertures NA>1 are possible during the immersion operation. A configuration as a dry lens is also possible; in this case, the image-side numerical aperture is restricted to values NA<1.

The projection exposure apparatus WSC comprises an operation control system configured to undertake a near-instantaneous fine optimization of imaging-relevant properties of the projection exposure apparatus in response to environmental influences and other disturbances and/or on the basis of stored control data. To this end, the operation control system comprises a multiplicity of manipulators which permit a targeted intervention in the projection behavior of the projection exposure apparatus. An actively activatable manipulator contains one or more actuating elements (or one or more actuators), the current manipulated value of which can be changed on the basis of control signals from the operation control system by virtue of defined manipulated value changes being undertaken.

The projection lens or the projection exposure apparatus is equipped, inter alia, with a wavefront manipulation system WFM which is configured to modify the wavefront of the projection radiation traveling from the object plane OS to the image plane IS in a controllable manner in the sense that the optical effect of the wavefront manipulation system can be variably adjusted by way of control signals from an operation control system.

For this purpose, the wavefront manipulation system in this exemplary embodiment comprises a manipulator MAN comprising a manipulator element ME that is arranged in the projection beam path in the immediate vicinity of the object plane of the projection lens. The manipulator element is substantially transparent to the utilized wavelength and comprises an entrance-side manipulator surface MS1 and an exit-side manipulator surface MS2, through which the projection beam path is guided. The optical effect of the manipulator element on the projection radiation passing through may be reversibly changed with the aid of an actuating device DR.

In an alternative to that or in addition, a manipulator element may be arranged e.g. in a pupil plane or in the optical vicinity thereof. The projection lens also comprises multiple further manipulators, which are not illustrated in detail here.

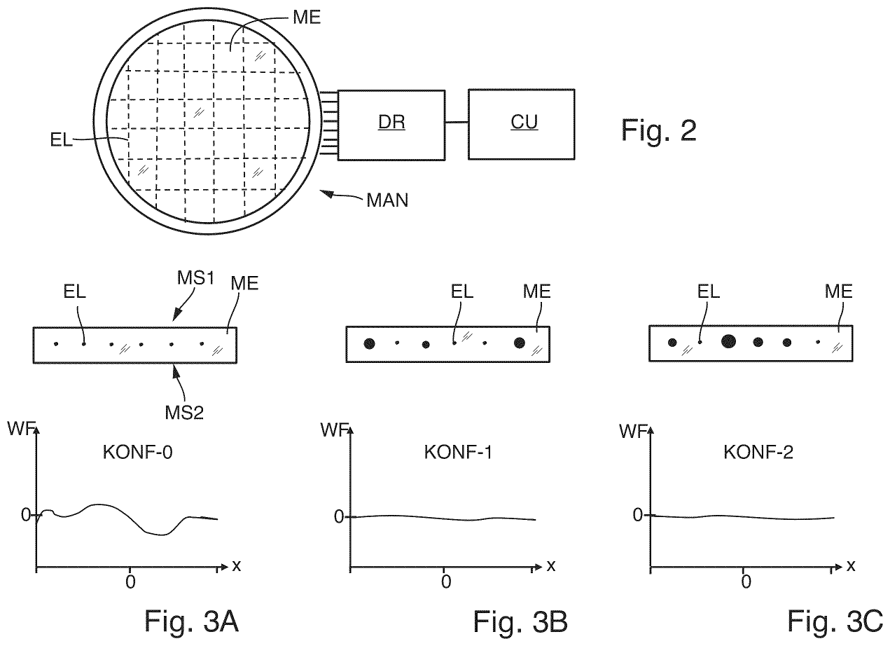

FIG. 2 schematically shows a plan view of an exemplary embodiment of a manipulator MAN. The manipulator MAN in the exemplary embodiment is designed to variably influence the wavefront of the passing projection radiation with a high spatial resolution in the radial direction and azimuthal direction in its optical used region through which the projection radiation passes. To this end, the manipulator comprises a manipulator element ME in the form of a plane-parallel plate which is made of material that is transparent to the projection radiation and in which different two-dimensional temperature profiles can be set over the optically used surface, in such a way that locally warmer zones can be produced next to locally colder zones. For this purpose, provision is made for devices that allow specific amounts of heat to be able to be supplied to each point in the radiation-transmissive region in a targeted manner, in order to generate a non-uniform temperature profile. In this case, the heating device works against the action of a cooling device that supports cooling processes.

The method of operation of the manipulator is similar to that of a heatable rear window. Conductor tracks EL (see FIG. 3A) made of an electrically conductive material, which as heating conductor material has a certain electrical resistance, extend along and/or in the manipulator element ME. The conductor tracks are relatively thin (e.g. have a width of less than 50 μm) and extend like a square grid in the exemplary case in a manner electrically insulated from one another with a pitch in the x-direction and y-direction. As a result, the optical effect of the manipulator element can be influenced in a spatially resolved manner by appropriate selective activation of the conductor tracks by virtue of a heating current used for heating being sent through a conductor track. Here, use is made of the temperature dependence of the optical refractive index of the transparent material of the manipulator element. By controlling the temperature in the individual regions, it is possible to vary the optical path length between the entrance-side manipulator surface MS1 (entrance surface) and the exit-side manipulator surface MS2 (exit surface). In this case, the phase change caused in the transmitted light is approximately proportional to the temperature change for a given geometry of the manipulator element.

When the manipulator element is not activated by virtue of the conductor tracks being currentless and there being no active cooling of the manipulator element, a passing wavefront is virtually unchanged since the optical path length for the radiation is substantially the same at all locations of the optical used region. By contrast, if a temperature distribution with zones of different temperature is created by applying current to corresponding conductor tracks, then an optical wavefront passing through the manipulator element experiences a wavefront deformation which correlates with the set temperature profile. Conversely, a deformed wavefront can be corrected by a suitable inverse temperature profile. For example, electrically activatable manipulators operating according to this principle are disclosed in WO 2008/034636 A2 (corresponding to U.S. Pat. No. 8,891,172 B2, for example). The disclosure of the documents is incorporated by reference in the content of the description.

When the projection lens PO is produced, the latter is initially assembled by virtue of the numerous optical elements, which are used for the construction of the projection beam path and held in mounts on an individual basis or in groups, being assembled in accordance with structural specification in such a way that the projection beam path arises. The manipulator MAN is also installed in the process. After the first assembly, the imaging performance of the projection lens is generally still far away from the imaging performance desired in accordance with the specification.

Then a first loop of the adjustment is run through by virtue of some or all optical elements that can still be changed in terms of their position in the installed state being changed in terms of their rigid-body degrees of freedom such that the imaging performance is improved. To this end, optical elements, i.e. lens elements and/or mirrors, can be displaced or rotated or tilted e.g. transversely to the reference axis (optical axis) and/or parallel thereto. This first adjustment process is carried out with monitoring by an aberration measurement in order to check the effects of the changes on the manipulators and in order to derive operating instructions for further manipulators.

During these first adjustment steps, the manipulator MAN is not activated, and so there is a homogeneous refractive index over the entire used cross section within the plane plate. During this phase, the manipulator thus only has the optical effect of a transparent plane plate, which in this case corresponds to the optical effect provided for this optical element in accordance with the underlying optical design. This special initial configuration of the manipulator element is also referred to as “neutral configuration” in this application since the manipulator element exerts its intended effect according to optical design. In this state of the projection lens, the wavefront of the projection radiation that is ascertained by measurement will deviate from the wavefront sought-after according to the specification, i.e. there is a wavefront error.

This is followed by the calculation of a first configuration of the manipulator element, which is distinguished in that the wavefront error would be compensated for or corrected if the manipulator element were present in the first configuration. In the exemplary case of the manipulator element that can be heated to different extents locally, the first configuration would accordingly correspond to a certain local distribution of the refractive index of the manipulator element in the optically used cross section or a corresponding two-dimensional temperature profile or heating profile. If the manipulator element were then brought into the first configuration after the measurement, the ascertained wavefront error would be compensated for more or less completely.

Experience has shown that a single such adjustment loop is usually not sufficient to reliably ensure that the projection lens meets the specifications. In general, the adjustment process therefore is an iterative process, in which multiple adjustment loops are run through, with individual manipulator elements or all manipulator elements still being changed between the individual adjustment loops. The effect of activating the manipulator of the wavefront manipulation system can be taken into account only by way of simulation during the adjustment, without the manipulator actually being activated, while the adjustments are actually implemented at the other manipulators. The adjustment loops are then run through such that the adjustment process converges in such a way that the imaging performance is brought as close to the specification performance as is possible by settings on the other manipulators.

Once this state has been reached, the nature of the first configuration of the manipulator MAN or of the manipulator element used to correct the remaining residual aberrations is established by a further measurement. A first mode of operation of the control unit is defined on the basis thereof. In the first mode of operation, the control unit generates first control signals which prompt the actuating device to set the first configuration of the manipulator element. Hence the first mode of operation uses a prescription for activating the manipulator such that it adopts the first configuration and hence corrects the residual aberrations.

To illustrate this procedure, FIGS. 3A-C show different configurations of the manipulator and the optical effect thereof in each of the three partial FIGS. 3A, 3B and 3C. At the top, each partial figure shows a schematic cross section through the transparent, plane-parallel manipulator element ME with the conductor tracks EL extending therein. Beneath this, there is a respective diagram with a schematic illustration of a selected wavefront error WF (e.g. distortion) as a function of the location on the x-axis in the corresponding configuration of the manipulator element.

All conductor tracks EL are currentless in the situation in FIG. 3A; this is represented by the uniform small point size. This configuration corresponds to a neutral configuration KONF-0 of the manipulator element. The diagram shows the spatial profile of the wavefront error WF after the adjustment has been completed, in the situation in which the manipulator is in this neutral configuration KONF-0. There is a significant location-dependent wavefront error WF.

In this manipulator principle, another possibility for setting the neutral configuration lies in already applying electrical power to the conductor tracks but compensating the effect of the heating caused thereby by way of appropriate cooling such that the manipulator is already activated but the optical effect of the manipulator element nevertheless corresponds to that of the non-activated passive mode (without heating and cooling). This type of neutral configuration thus is operation in the active, switched-on state in which cooling power and counter-heating maintain equilibrium spatially in all zones, and so the temperature is constant over the glass plate that serves as manipulator element. Incidentally, this need not mean that the electrical heating power (or current) is the same for all zones. Regarding details of such calibrations, reference should be made to DE 10 2013 225 381 A1.

FIG. 3B shows the manipulator element in its first configuration KONF-1, which is adopted when the control unit CU is switched into the first mode of operation. In the configuration shown, the manipulator element ME is heated to different extents locally by way of different degrees of application of current to the conductor tracks (corresponding to conductor track symbols of different thicknesses), and so a non-uniform temperature profile arises over the used surface. In the exemplary case, this is calculated in such a way that the wavefront error still present in the situation of FIG. 3A is largely compensated for, and hence it is close to zero over the entire used cross section. In this first operating mode, the manipulator MAN thus develops that effect which was achieved by the individually produced correction aspheres in conventional methods.

However, this compensatory effect is generated using a dynamically variable manipulator MAN, the setting range (range) of which starting from this first configuration also offers the possibility of compensating, by a correspondingly adapted modified temperature profile, the further wavefront errors that may occur during the further operation of the projection exposure apparatus. The upper partial figure of FIG. 3C schematically shows how heating current is applied to the conductor tracks to a non-uniform extent in some other way in a second configuration KONF-2 deviating from the configuration in FIGS. 3A and 3B, and so the wavefront errors occurring later during operation are corrected to such an extent that this ensures virtually error-free imaging with wavefront errors at or close to zero.

The assembly and the measurement-assisted adjustment generally take place at the projection lens manufacturer.

In general, the adjustment will then result in a configuration in which the projection lens has a non-tolerable wavefront error for as long as the installed manipulator element is in its neutral configuration (without activation by the control unit). According to the method proposed here in the case of the adjustment, the installed, spatially resolvably activatable, thermal manipulator MAN with an activated heating profile is used simulatively for the wavefront optimization. The temperature profile associated with the first configuration KONF-1 therefore need not actually be generated.

However, a first operating data record is stored in a data memory accessible to the control unit CU, the operating data record representing the first operating mode and hence enabling the control unit to use the specifications in the data record as a basis in order to set the manipulator element in the first configuration, which is suitable for reducing the wavefront error of the assembled projection lens to such an extent that the imaging performance meets the specifications (cf. FIG. 3B). Hence, the delivery encompasses a heating profile that is set when the projection lens is put into operation in order to achieve the certified performance. In other words: Each projection lens is delivered when dispatched together with an individual heating profile that is constant over time and differs from the neutral profile (neutral configuration) and corresponds to the first configuration of the manipulator element. Initially, the projection lens only meets the specification if the manipulator is activated in the first mode of operation.

This procedure can replace the conventional procedure whereby at least one (invariable) correction asphere was generated on the basis of the measurements at the manufacturer and then installed in order to ensure that the projection lens meets the specifications prior to dispatch. It is thus possible to omit the corresponding manufacturing-related outlay when performing surface processing on the manipulator surface. The omission of the processing step for producing individually adapted correction aspheres results in a considerable shortening of the throughput times for generating the correction effect.

In this process, use can be made of a variably adjustable manipulator MAN, which has not yet been individualized for the specific projection lens when installed and which also only adopts by way of an appropriate activation profile a first configuration that in terms of its effect corresponds to the effect of a conventional correction asphere.

The manipulator can retain its variability, and so it may also be used for the compensation of additional wave aberrations that may arise at a later stage during the lifespan of the projection lens, e.g. on account of “lens heating” (cf. FIG. 3C, for example). For series production, it is to be noted here that all installed manipulators of the same type in fact have the same neutral configuration in the delivery state of the system. In that case, the correction effect is attained with the aid of the activated manipulator only by activation according to the prescription, ascertained during the measurement, for setting the first configuration.

This concept considerably increases the useful lives of the projection lenses available for the end user. Should an installed manipulator be in need of maintenance or in need of repair, it can be removed from the projection lens on site at the user and be replaced by an identically constructed variable manipulator which, just like the exchanged manipulator, of course, is present without activation in its neutral configuration. Then, the heating profile suitable for compensating the current wavefront errors can be set purely by a suitable activation by way of the control unit. For a repair measure in the field, it is hence possible to use any desired manipulator of the same construction as a replacement part.

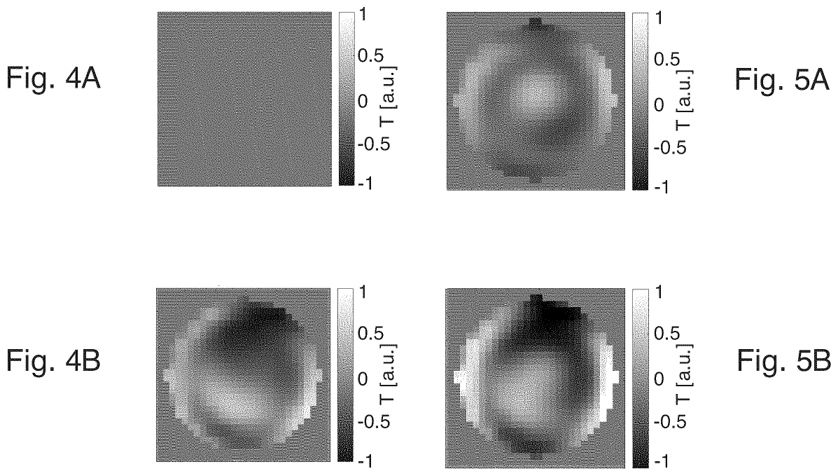

In order to yet again illustrate certain differences between conventional methods with installed manipulators and methods according to the proposal in this application, FIGS. 4A and 4B show schematic illustrations of two-dimensional heating profiles according to a conventional method and FIGS. 5A and 5B show the heating profiles according to an exemplary embodiment of the method presented in this application. All figures show a two-dimensional representation of a manipulator element, in which the local temperatures T (in arbitrary units, a.u.) are represented by grayscale levels. The neutral gray in FIG. 4A corresponds to a reference temperature, brighter levels of gray correspond to upward deviations in the local temperature and darker regions correspond to downward deviations in the local temperature. The deviations are usually in the order of fractions of a kelvin.

Conventionally, an installed dynamic manipulator was used purely for the compensation of wavefront aberrations that arose only during operation. Accordingly, the manipulator had its neutral configuration with a uniform temperature over the entire used region in the delivery state, and so the optical effect over the cross section corresponded to that of a plane plate (FIG. 4A). In order to correct residual aberrations remaining after the adjustment, a specially adapted correction asphere was manufactured and installed. During the operation of the projection exposure apparatus at the end customer, the manipulator was activated when desied in order to correct imaging errors by modifications of the local heating profile (cf. FIG. 4B).

In the adjustment method presented herein, the manipulator is already used at commissioning as an adjustment mechanism for attaining the imaging performance as per specification. To this end, a heating profile is simulated, the latter being designed such that the specification applicable for commissioning is achieved in combination with the previous adjustment mechanism. This heating profile is made available to the end customer by virtue of a corresponding data record being stored in a memory accessible to the control unit and these values being able to be retrieved for the generation of the first mode of operation. This means that, in general, the heating profile of the manipulator no longer corresponds to a neutral profile at time of purchase by the customer but that there already is a spatially non-uniform temperature distribution (according to a first configuration) with a corresponding effect on the wavefront (FIG. 5A). In this case, this effect corresponds to the effect of the conventional correction asphere. During operation at the end customer, the manipulator may however then also be used as previously in order to correct imaging errors by modifying the heating profile (FIG. 5B). The activation of the manipulator in a specific situation during operation may thus be regarded as two stage. In this case, the actually set heating profile is the sum of the heating profile at commissioning (FIG. 5A) and the activation profile at the customer for compensating for the wavefront error which has occurred as a result of operation.

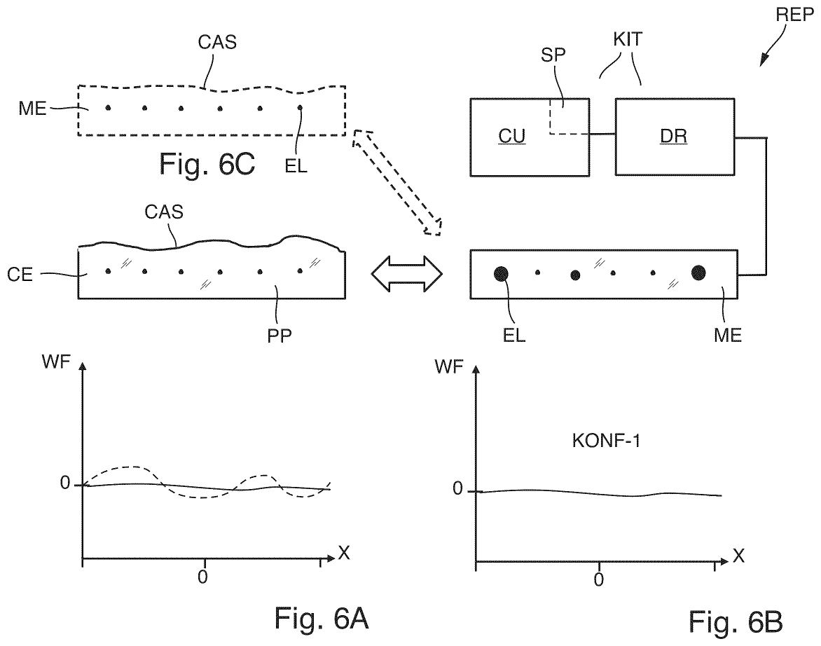

Further aspects and features and optional uses of the disclosure are explained on the basis of FIGS. 6A, 6B and 6C. The features of the disclosure can also be used for the repair or maintenance of projection lenses which, after prolonged use, foreseeably cannot fulfill the desired specification for much longer.

In the schematically illustrated exemplary embodiment of FIGS. 6A and 6B, the original production ensured the specification was met for the projection lens after completion of the adjustment in solid-body degrees of freedom by way of an individually manufactured correction asphere CAS. To this end, a plane plate PP provided in the design for this purpose was provided with a correction asphere CAS on its entry face (or exit face) on the basis of wavefront measurements via ion beam etching with location-dependently varying material removal, the correction asphere allowing the correction of the residual aberrations at the time of production. In the upper partial figure, FIG. 6A shows the correction element CE produced as a result, on the entry face of which the correction asphere CAS was produced. The exit side retained its planar initial shape. By way of a solid line, the lower partial figure shows the resultant wavefront error at the time, which is close to zero over the entire field. Over the course of operation, the aberration level slowly increased to close to the specification limit (dashed line).

In the exemplary case, the projection lens is repaired or ensured to meet the specification again by virtue of the assembly containing the correction element CE being removed from the projection lens and a replacement assembly REP being installed in place thereof, the latter having been equipped with a manipulator element ME that can be heated locally to different extents and is of the type described in connection with FIGS. 2 and 3A-C. The manipulator element ME contains thin conductor tracks EL to which heating current can be applied, the application being variable to such an extent that a desired refractive index distribution is set over the used cross section. The replacement assembly REP containing this manipulator element also comprises the associated actuating devices DR. These hardware components are part of a repair kit KIT, which also comprises adapted software components in addition to this hardware component. In the exemplary case, this includes a first operating data record, which is stored in a memory SP of the control unit CU.

The actuating device DR that acts on the manipulator element can be operated in such a way on the basis of the first operating data that the manipulator element ME has substantially the same optical effect as the removed correction element CE with the invariable correction asphere CAS. Additionally, a correction profile can be applied electronically, the latter also compensating for the residual errors that are built up over time, and so the residual aberrations again have a tolerable level with only small fluctuations over the field when the manipulator element ME is activated in the first mode of operation. FIG. 6B thus schematically illustrates the hardware and software components of a repair kit, with the aid of which the degraded projection lens can be ensured to meet the specifications again.

A different scenario is explained on the basis of FIGS. 6C and 6A in combination. In this alternative initial situation (represented by dashed lines), the correction element provided with a permanent correction asphere CAS and originally installed in the projection lens is itself a correction element that can be manipulated by appropriate actuating devices on the basis of control commands from the control unit, i.e. it is a manipulator element ME. In the example of FIG. 6C, this is a transparent plate in which heating conductors EL have been incorporated, by which it is possible to set a selectable heating profile and hence a desired refractive index distribution over the used cross section (cf. FIGS. 2 and 3A-C, for example). Within the scope of the first production, such a manipulator can assume a dual function by not only retaining the potential for the later dynamic wavefront manipulation but also by additionally compensating the residual aberrations, present after the adjustment, via a correction asphere generated on a surface of the manipulator element.

Hence, it is possible for example to replace an optical element for which repair or maintenance is desired, the latter having been provided with a conventional correction asphere in order to originally ensure that the projection lens meets the specification. In this context, this optical element is replaced by a manipulator of the type described herein, which has a first mode of operation that adopts the effect of this correction asphere and is able to dynamically correct in addition effects that may arise on account of the operation. The operating data for setting the first mode of operation may be calculated in this case on the basis of the known effect data of the originally installed correction asphere without further measurement. Alternatively, the first operating data may be calculated on the basis of a field-point-resolved wavefront measurement for the lens to be repaired and for the manipulator to be newly installed, in a neutral configuration. In that case, the first mode of operation may also take other aging effects of the lens into account.

Phrased somewhat more generally, a manipulator involving repair or maintenance and with or without a permanent correction asphere can be replaced by a manipulator of the novel type, the latter being operated in the first mode of operation in order to ensure that the projection lens meets the specifications.

Repair scenarios that involve replacing other optical elements in need of maintenance or repair, i.e. optical elements without a correction asphere, are also conceivable. For example, a manipulator having a conventional correction asphere or else a manipulator having a first operating state may be installed. According to this scenario, the replacement of the other optical elements results in wavefront errors that were hitherto possible only by way of replacing the correction asphere on a manipulator and hence the entire manipulator. It is now possible for the first time to configure or re-configure the installed manipulator for the manipulator such that a first operating state is assumed, the latter correcting the residual aberrations present after the exchange to a sufficiently good extent.

This application also discloses concepts of recycling still functional manipulators which have already been used for a certain time in a projection lens and can now be used in another projection lens, for example in a projection lens to be repaired. For explanatory purposes, reference is initially made to FIG. 6C. The latter shows a dynamically activatable manipulator element ME with built-in heating conductors EL, the manipulator element having been provided with a correction asphere CAS individually adapted for a first projection lens during its first use in the projection lens. As it were, the manipulator element has a “history”. Just like the manipulator element in FIG. 6B, the manipulator element is suitable for being dynamically activated by corresponding actuating devices with the aid of a control unit (not depicted in FIG. 6C). This functionality may also be used in recycling scenarios. One scenario comprises the removal of such a still functional manipulator, which had a conventional correction asphere and had hitherto been operated conventionally without using the disclosure, from an old projection lens and the reuse of the manipulator in a projection lens to be repaired, the latter for example having been operated with a corresponding manipulator that, however, lacked a correction asphere.

The newly installed, already used and now recycled manipulator may now be operated in a first operating state that compensates firstly for the effect (not fitting the projection lens to be repaired) of the correction asphere CAS (which fits the previous projection lens) and also, however, for the residual aberrations that set in after the initial assembly of the repaired projection lens. Moreover, the travel (range) of the manipulator is also sufficient to dynamically compensate for aberration components that might arise during the operation of the repaired projection lens. Accordingly, such a recycled, used manipulator element with a history may also be used to replace another manipulator element equipped with a different correction asphere in a projection lens to be repaired (or in a projection lens to be newly produced).

Some aspects of the novel concept have been explained on the basis of the example of a manipulator MAN, which has a manipulator element ME transparent to the radiation to be influenced and has a spatially dependent effect on the wavefront of the transmitted radiation by way of setting different non-uniform temperature profiles in the used region. Numerous manipulators that operate according to other principles may be used analogously within the scope of exemplary embodiments of the disclosure. For example, use can thus be made of at least one manipulator with an optically transparent manipulator element which is locally deformable to different extents in response to control signals. Examples thereof are described in U.S. Pat. No. 9,651,872 B2 or U.S. Pat. No. 10,061,206 B2, for example. DE 10 2020 212 742 A1 (corresponding to WO 2022/074022 A1) describes manipulators which use a dielectric medium connected to electrodes for changing the shape of an optical surface. The manipulator element might be a mirror with a deformable mirror surface, which is configured to reflect EUV radiation. For example, the EUV radiation might have wavelengths from the range from 6 nm to 20 nm, for example approx. 13.5 nm or 6.8 nm. DE 198 24 030 A1 discloses a catadioptric projection lens having a concave mirror that can be deformed in a targeted manner in order to correct wavefront errors.

In the exemplary case, the manipulator is arranged in the optical vicinity of the object plane, i.e. in the optical vicinity of a field plane. As a result, correction effects of different strengths can be achieved for different field points. Something similar would be possible in the case of an arrangement in the vicinity of another field plane, e.g. in the case of an arrangement in the vicinity of a real intermediate image. In an alternative to that or in addition, a manipulator may also be arranged in or in the vicinity of a pupil plane, and so changes that differ in spatially dependent fashion have an effect on the projection radiation in angular space. An arrangement in an intermediate region between the field plane and pupil plane is also possible.

What is claimed is:

1. A method, comprising:
assembling a projection lens by arranging a multiplicity of optical elements so that optical surfaces of the optical elements define a projection beam path so that the optical elements are configured to image a pattern in an object field of an object plane of the projection lens into an image field of an image plane of the projection lens;
installing a manipulator of a wavefront manipulation system that is configured to dynamically influence a wavefront of the projection radiation in response to control signals from a control unit of the wavefront manipulation system, the manipulator comprising a manipulator element comprising a manipulator surface in the projection beam path, the manipulator further comprising an actuating device which is controllable by control signals from the control unit and which is configured to reversibly change the optical effect of the manipulator element;
determining spatially resolved wavefront errors of the wavefront, wherein the manipulator element has an initial configuration during the measurement, the initial configuration serving to establish an initial state of the projection lens after assembly;
calculating a first configuration of the manipulator element that is suitable for correcting the wavefront errors; and
defining a first mode of operation of the control unit, the control unit generating first control signals in the first mode of operation, and the first control signals prompting the actuating device to set the first configuration of the manipulator element.

2. The method of claim 1, wherein:
the initial configuration of the manipulator element is a neutral configuration; and
in the neutral configuration, an optical effect of the manipulator element corresponds to a target effect of the manipulator element in accordance with an optical design of the projection lens so that the neutral configuration is a configuration that the manipulator element would have if all optical surface of the projection lens, including the manipulator element, were embodied exactly in accordance with the intended configuration that emerges from the optical design calculations.

3. The method of claim 1, wherein:
installing the projection lens in a projection exposure apparatus is followed by using the projection lens in a production operation at a use location; and
starting the production operation is preceded by switching the control unit at the use location into the first mode of operation and generating first control signals which prompt the actuating device to set the first configuration of the manipulator element.

4. The method of claim 1, comprising:
storing a first operating data record representing the first mode of operation in a data memory accessible to the control unit; and
retrieving the first operating data record from the data memory for setting a first mode of operation of the control unit, wherein in the first mode of operation, the control unit generates first control signals which prompt the actuating device to set the first configuration of the manipulator element.

5. The method of claim 1, wherein:
the control device is operable in multiple modes of operation; and
in addition to the first mode of operation, there is a second mode of operation in which the manipulator element has a second configuration that has a different optical effect than the first configuration.

6. The method of claim 1, comprising installing a second manipulator.

7. The method of claim 1, wherein:
activating the manipulator to set the first configuration is taken into account by simulation during the adjustment, without the manipulator being activated, with effects of the at least one further manipulator actually being implemented; and/or
the adjustment operation is performed iteratively in multiple adjustment loops until a first configuration is found which is suitable for sufficiently compensating all residual aberrations of the projection lens, including those originating from other manipulators present in the projection lens.

8. The method of claim 1, wherein:
the manipulator comprises a mirror comprising a deformable mirror surface or the manipulator element comprises a transparent optical element; and
the manipulator is heated and/or cooled to different extents at different locations in a used region electrically or in any other way to change the local refractive index distribution.

9. The method of claim 1, wherein a manipulator surface is coated with an optical functional layer prior to installation in the projection lens.

10. The method of claim 1, wherein the manipulator is removed from the projection lens, and, after removal, the manipulator is used as a manipulator in a different projection lens.

11. The method of claim 1, wherein:
the initial configuration of the manipulator element is a neutral configuration in which an optical effect of the manipulator element corresponds to a target effect of the manipulator element in accordance with an optical design of the projection lens;
installing the projection lens in a projection exposure apparatus is followed by using the projection lens in a production operation at a use location; and
starting the production operation is preceded by switching the control unit at the use location into the first mode of operation and generating first control signals which prompt the actuating device to set the first configuration of the manipulator element.

12. The method of claim 1, wherein:
the initial configuration of the manipulator element is a neutral configuration in which an optical effect of the manipulator element corresponds to a target effect of the manipulator element in accordance with an optical design of the projection lens; and
the method comprises:
storing a first operating data record representing the first mode of operation in a data memory accessible to the control unit; and
retrieving the first operating data record from the data memory for setting a first mode of operation of the control unit, wherein in the first mode of operation, the control unit generates first control signals which prompt the actuating device to set the first configuration of the manipulator element.

13. A projection lens, comprising:
a multiplicity of optical elements configured so that optical surfaces of the optical elements define a projection beam path so that the optical elements are configured to image a pattern in an object filed in an object plane of the projection lens into an image field in an image plane of the projection lens;
a wavefront manipulation system comprising a manipulator and a control unit, the manipulator configured to dynamically influence a wavefront of projection radiation in response to control signals from the control unit,
wherein:
the manipulator comprises a manipulator element comprising a manipulator surface in the projection beam path;
the manipulator comprises an actuating device controllable by control signals from the control unit to reversibly change an optical effect of the manipulator element;
the manipulator element has an initial configuration;
the projection radiation has wavefront errors during operation in the initial configuration of the manipulator element;
a first operating data record representing a first mode of operation is stored in a data memory accessible to the control unit; and
the control unit is configured to generate first control signals in the first mode of operation, the first control signals prompting the actuating device to set a first configuration of the manipulator element that is suitable for correcting the wavefront errors.

14. The projection lens of claim 13, wherein:
the manipulator comprises a mirror comprising a deformable mirror surface or the manipulator element comprises a transparent optical element;
the manipulator is heatable or coolable to different extents at different locations of a used region electrically or in any other way in order to change the local refractive index distribution.

15. An apparatus, comprising:
an illumination system; and
a projection lens according to claim 13,
wherein the illumination system is configured to illuminate the object field of the object plane, and the apparatus is a microlithography projection exposure apparatus.

16. A method of using a projection exposure apparatus comprising an illumination system and a projection lens, the method comprising:
using the illumination system to illuminate a region of an object in an object field of an object plane of the projection lens mask;
using the projection lens to project the illuminated region of the object into an image field of an image plane of the projection lens via projection radiation,
wherein the projection lens is a projection lens according to claim 13.

17. A method of using a projection exposure apparatus comprising an illumination system and a projection lens, the method comprising:
using the illumination system to illuminate a region of an object in an object field of an object plane of the projection lens mask;
using the projection lens to project the illuminated region of the object into an image field of an image plane of the projection lens via projection radiation;
influencing a wavefront of the projection radiation traveling from the object plane to the image plane by activating a manipulator, the manipulator comprising a manipulator element comprising a manipulator surface in a beam path of the projection radiation, the manipulator further comprising an actuating device configured to reversibly change an optical effect of the manipulator element, the manipulator element having an initial configuration in an absence of control signals, the projection radiation has wavefront errors in the initial configuration of the manipulator element; and
based on a first operating data record representing a first mode of operation of the manipulator element, using the actuating device to switch the manipulator element from the initial configuration to the first mode to a first configuration to correct the wavefront errors.

18. A method of repairing a projection lens comprising a multiplicity of optical elements configured so that optical surfaces of the optical elements define a projection beam path by which an object in an object field of an object plane of the projection lens is imaged into an image field of an image plane of the projection lens, the multiplicity of optical elements comprising a fixed correction asphere configured to influence a local wavefront two-dimensionally in a region in the projection beam path, the method comprising:
removing an assembly comprising the fixed correction asphere;
installing a replacement assembly which comprises a wavefront manipulation system comprising a control unit and a manipulator, the manipulator configured to dynamically influence a wavefront of the projection radiation in response to control signals from the control unit, the manipulator comprising a manipulator element comprising a manipulator surface in the projection beam path, the manipulator comprising an actuating device controllable by control signals from the control unit and serving to reversibly change an optical effect of the manipulator element,
wherein:
the manipulator element has an initial configuration;
the projection radiation has wavefront errors during operation in the initial configuration of the manipulator element;
a first operating data record representing a first mode of operation is stored in a data memory accessible to the control unit;
the control unit is configured to generate first control signals in the first mode of operation;
the control signals prompting the actuating device to set a first configuration of the manipulator element in which the manipulator element substantially has the optical effect of the removed correction asphere.

19. The method of claim 18, wherein the fixed correction asphere comprises a manipulator element of a manipulator comprising an actuating device which is controllable by control signals from the control unit and serves for reversibly changing the optical effect of the manipulator element.

20. The method of claim 18, wherein the fixed correction asphere is a non-manipulable correction element having a correction asphere.
